(19) United States
(12) Patent Application Publication
(10) Pub. No.: US 2024/0429891 A1
(43) Pub. Date: Dec. 26, 2024

(54) NONLINEARITY-ASSISTED TEMPERATURE COMPENSATION OF MECHANICAL RESONATORS, OSCILLATORS, AND CLOCKS

(71) Applicant: University of Florida Research Foundation, Incorporated, Gainesville, FL (US)

(72) Inventor: Roozbeh Tabrizian, Gainesville, FL (US)

(21) Appl. No.: 18/739,426

(22) Filed: Jun. 11, 2024

Related U.S. Application Data
(60) Provisional application No. 63/509,120, filed on Jun. 20, 2023.

(51) Int. Cl. H03H 9/02

(52) U.S. Cl. CPC H03H 9/02102

(57) ABSTRACT

Methods and systems are directed to compensating a frequency drift of a mechanical resonator due to temperature change. The method includes, in part, generating a drive voltage and applying the drive voltage to the mechanical resonator, wherein the drive voltage excites elastic nonlinearity of the mechanical resonator and generates a temperature-dependent force or displacement enabling the mechanical resonator to compensate the frequency drift. The drive voltage can have a constant magnitude or a temperature-dependent magnitude. The drive voltage with a constant magnitude may be applied to a piezoelectrically-actuated resonator comprising a piezoelectric layer and a plurality of semiconductor layers, wherein thicknesses of the piezoelectric layer and the plurality of semiconductor layers are designed so that the desired temperature-dependent force or displacement can be generated with the applied drive voltage. The drive voltage with a temperature-dependent magnitude may be generated by controlling a transduction gap of a capacitively-actuated resonator, or by controlling a loop gain of an oscillator comprising the mechanical resonator using a transimpedance amplifier with temperature-controlled gain or a temperature-controlled impedance.

### CROSS REFERENCE TO RELATED APPLICATIONS

This application claims priority to U.S. Application No. 63/509,120 filed Jun. 20, 2023, the contents of which are hereby incorporated in their entirety by reference.

### BACKGROUND

An oscillator can be used to establish a reference frequency used for timing purposes. Thus, stability of an oscillator is vital for many applications, such as wireless communications, positioning, and navigation. Oscillators based on quartz crystal resonators have traditionally been the dominant choice for the industry. However, they are not suitable for monolithic integration with integrated circuit. Thus, miniaturized alternatives that have higher levels of integration with microelectronics are desired. Oscillators based on micromachined mechanical resonators (also referred to herein as electromechanical resonators) are promising alternatives due to various advantages, such as small form factors, low phase noise, good long-term stability, low cost, and compatibility with batch processing. However, the frequencies of oscillators based on mechanical resonators suffer from large temperature sensitivity. This sensitivity is due to temperature-induced changes in clastic constant and mass density of resonator material and resonator dimensions. Thus, there is a need for temperature compensation methods that can mitigate frequency variation and ensure frequency stability of the oscillators based on mechanical resonators.

### BRIEF SUMMARY

Embodiments of the present disclosure relate to temperature compensation methods that can mitigate frequency variation and ensure frequency stability of the oscillators based on mechanical resonators.

In one embodiment, a method is included. The method may be for compensating a frequency drift of a mechanical resonator due to temperature change by generating a drive voltage; and applying the drive voltage to the mechanical resonator, wherein the drive voltage (1) excites elastic nonlinearity of the mechanical resonator, and (2) generates a temperature-dependent force or displacement enabling the mechanical resonator to compensate the frequency drift.

In one embodiment, a system is included. The system may be for compensating a frequency drift of a mechanical resonator due to temperature change and include the mechanical resonator; and a subsystem coupled to the mechanical resonator, wherein the subsystem generates and applies a drive voltage to the mechanical resonator, wherein the drive voltage (1) excites elastic nonlinearity of the mechanical resonator, and (2) generates a temperature-dependent force or displacement enabling the mechanical resonator to compensate the frequency drift.

### BRIEF DESCRIPTION OF THE DRAWINGS

Reference will now be made to the accompanying drawings, which are not necessarily drawn to scale, and wherein:

FIGS. 1A-1F show an example evolution of temperature characteristic for a (100)-aligned Lamé resonator in phosphorous-doped Si;

FIG. 2A is an example resonator design, in accordance with some embodiments of the present disclosure;

FIG. 2B shows the simulated mode shape of the example resonator design in FIG. 2A when operating in cross-sectional Lame mode, in accordance with some embodiments of the present disclosure;

FIG. 3A shows a cross-sectional stack of an example resonator, in accordance with some embodiments of the present disclosure;

FIG. 3B shows simulated transmission response of the example resonator in FIG. 3A at different temperatures.

FIGS. 4A and 4B show the simulated temperature characteristic of the example resonator in FIG. 3A in a wide temperature range and in a small temperature range around the turn-over point, respectively, in accordance with some embodiments of the present disclosure;

FIG. 5 shows a cross-sectional stack of another example piezoelectrically-actuated resonator, in accordance with some embodiments of the present disclosure;

FIG. 6 is an example capacitively-actuated resonator, in accordance with some embodiments of the present disclosure;

FIG. 7 is an example embodiment of the disclosure based on controlling oscillator loop gain using local temperature sensing, in accordance with some embodiments of the present disclosure;

FIG. 8 is another example embodiment of the disclosure based on controlling oscillator loop gain using local temperature sensing, in accordance with some embodiments of the present disclosure;

FIG. 9A is another example embodiment of the disclosure based on controlling oscillator loop gain using local temperature sensing, in accordance with some embodiments of the present disclosure;

FIG. 9B shows a relationship between an output voltage of a proportional to absolute temperature circuit and temperature, in accordance with some embodiments of the present disclosure;

FIG. 10 is another example embodiment of the disclosure based on controlling oscillator loop gain using local temperature sensing, in accordance with some embodiments of the present disclosure;

### DETAILED DESCRIPTION OF VARIOUS EMBODIMENTS

Various embodiments of the present disclosure now will be described more fully hereinafter with reference to the accompanying drawings, in which some, but not all embodiments of the disclosure are shown. Indeed, the disclosure may be embodied in many different forms and should not be construed as limited to the embodiments set forth herein. Rather, these embodiments are provided so that this disclosure will satisfy applicable legal requirements. The term “or” is used herein in both the alternative and conjunctive sense, unless otherwise indicated. The terms “illustrative,” “example,” and “example” are used to be examples with no indication of quality level. Like numbers refer to like elements throughout.

### Brief Overview

Depending on resonator operation mode, the resonance frequency is defined by elastic constants, mass density and dimensions. For example, for a Lamé mode excited in a square resonator aligned to (100) crystal orientation in single-crystal Si, the frequency f, when operating in linear regime, is defined by:

$$f - \frac{1}{L \sqrt{2}} \sqrt{\frac{G}{ρ}} . \qquad ( 1 )$$

Here, G represents the shear modulus, ρ is the density of silicon, and L is the length of the square resonator.

The temperature sensitivity of resonator is defined by temperature coefficients of frequency, wherein the i-th order temperature coefficient of frequency (TCfᵢ) is defined by:

$${TCf}_{i} = \frac{1}{i !} \frac{1}{f ( 0 )} \frac{{\partial }^{i} f}{\partial {T}^{i}} . \qquad ( 2 )$$

Here, Tis the temperature in Kelvin (K), and f(0) is the resonant frequency of the resonator at a temperature of 0 K.

The resonator frequency as a function of temperature is then given by:

$$f ( T ) = f ( 0 ) ( 1 + {\sum }_{i \geq 1} {TCf}_{i} {T}^{i} ) . \qquad ( 3 )$$

However, when exciting resonator with larger force, the frequency shifts from Eq. (1) due to elastic nonlinearities. The frequency shift due to these nonlinearities is governed by:

$${f}_{u + Δ u} = {f}_{u + Δ u} ( 1 + κΔ {u}^{2} ) . \qquad ( 4 )$$

Here, u and Δu are displacement and its differential, and x is the amplitude-frequency coefficient which is a function of nonlinear elasticity and dimensions of resonator.

The temperature-characteristic in nonlinear regime is then given by:

$${f}_{u} ( T ) = {f}_{u \to 0} ( 0 ) ( 1 + {\sum }_{i \geq 1} {TCf}_{i} {T}^{i} ) + κ {u}^{2} . \qquad ( 5 )$$

In nonlinear regime, the displacement is governed by:

$${M}_{eq} \ddot{u} + {D}_{eq} \dot{u} + {K}_{0} u + {K}_{1} {u}^{2} + {K}_{2} {u}^{3} = F . \qquad ( 6 )$$

Here, M_{eq} and D_{eq} are lumped-equivalent mass and damping of resonator. Kₒ, K₁, and K₂ are linear, quadratic and cubic lumped-equivalent spring constants of the resonator. F is the lumped-equivalent force exerted on resonator to induce a displacement u.

Considering the exerted force on resonator is temperature-sensitive and results in a temperature-sensitive displacement function given by:

$$u ( T ) = u ( 0 ) + \frac{du}{dT} T + \frac{{d}^{2} u}{{dT}^{2}} {T}^{2} . \qquad ( 7 )$$

The temperature-characteristic of resonator considering nonlinearity is then given by:

$$f ( T ) ≅ f ( 0 ) [ 1 + {TCf}_{1} T + {TCf}_{2} {T}^{2} + {TCf}_{3} {T}^{3} + {TCf}_{4} {T}^{4} ] + {κ [ u ( 0 ) + \frac{du}{dT} T + \frac{{d}^{2} u}{{dT}^{2}} {T}^{2} ]}^{2} - {κ [ u ( 0 ) ]}^{2} . \qquad ( 8 )$$

This can be further simplified to:

$$f ( T ) ≅ f ( 0 ) [ 1 + {TCf}_{NL , 1} T + {TCf}_{NL , 2} {T}^{2} + {TCf}_{NL , 3} {T}^{3} ] . \qquad ( 9 )$$

Here, TCf_{NL,i} are nonlinearity-assisted temperature coefficients given by:

$$\{ \begin{matrix}{TCf}_{NL , 1} = {TCf}_{1} + 2 κ u ( 0 ) \frac{du}{dT} \\ {TCf}_{NL , 2} = {TCf}_{2} + κ {( \frac{du}{dT} )}^{2} + 2 κ u ( 0 ) \frac{{d}^{2} u}{{dT}^{2}} \\ {TCf}_{NL , 3} = {TCf}_{3} + 2 κ \frac{du}{dT} \frac{{d}^{2} u}{{dT}^{2}} \\ {TCf}_{NL , 4} = {TCf}_{4} + κ {( \frac{{d}^{2} u}{{dT}^{2}} )}^{2}\end{matrix} . \qquad ( 10 )$$

Based on Eq. (10), temperature-characteristics of resonator can be tailored by opting for force functions F (and correspondingly u) with desirable magnitude and temperature-functionality. It is worth noting, the tailoring depends on the sign of amplitude-frequency coefficient κ.

Embodiments of the present disclosure may rely on using a force, F, with a desirable temperature-functionality/dependency, to stabilize inherent temperature sensitivity of the resonator operating in nonlinear regime. Various embodiments of the disclosure generally relate to methods and systems that create such temperature-dependent force function and/or use the force to stabilize inherent temperature sensitivity of the resonator operating in nonlinear regime.

### Example Methods and Apparatus Architecture for Implementing Embodiments of the Present Disclosure

Various embodiments of the disclosure relate to methods and systems that leverage temperature-dependent nonlinearity in resonator operation to compensate frequency variations due to temperature-induced changes in elasticity, density, and dimensions, which enables realization of oscillators and clocks with ultra-high temperature stability.

In some embodiments of the disclosure, an appropriate voltage may be selected for a resonator to create a temperature-dependent force function for achieving frequency stability within a temperature range.

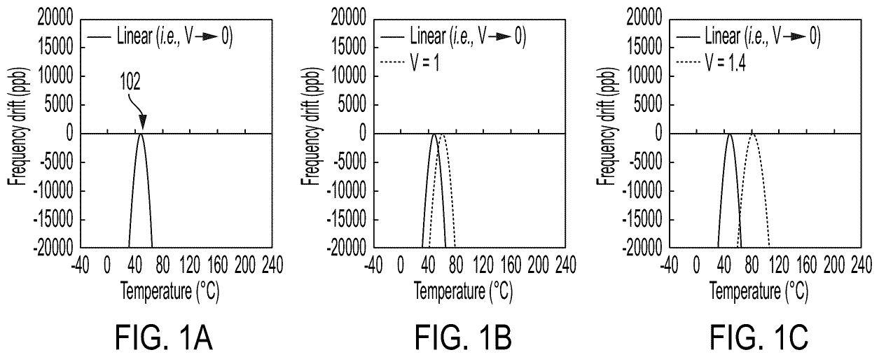

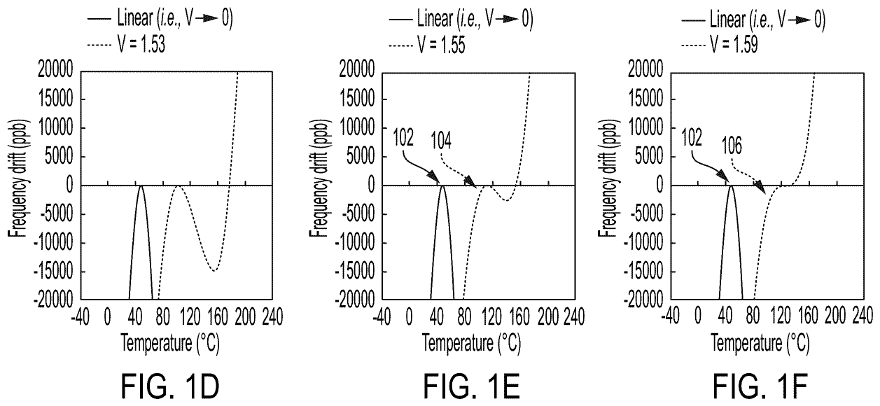

FIGS. 1A-1F show an example evolution of temperature characteristic for a (100)-aligned Lamé resonator in phosphorous-doped Si, assuming a voltage-scalable resonator displacement of:

$$u ( T ) = V ( 15 \times {10}^{- 9} + 1 \times {10}^{- 11} T + 5 \times {10}^{- 13} {T}^{2} ) . \qquad ( 11 )$$

Here V is the voltage that enables tuning the magnitude of displacement.

The change in temperature-characteristic is demonstrated in FIGS. 1A-1F. With increasing V, the turn-over temperature is shifting upward and the TCf_{NL,2} is reducing. For example, as shown in FIG. 1E, when V=1.55 V, the turn-over temperature of the frequency drift curve 104 of the resonator is shifted upward compared with that of the frequency drift curve 102 obtained when V=0 V. In addition, the curvature of the frequency drift curve 104 at the turn-over temperature is smaller than that of the frequency drift curve 102, which demonstrates that the second-order nonlinearity-assisted temperature coefficient is reduced. Similar phenomena can be clearly observed in FIG. 1F from the frequency drift curve 106 with V=1.59 V, which also shows that the TCF₂ of the resonator is significantly compensated compared with that when V=0 V. This results in frequency stability of the resonator over a much wider temperature range.

In some embodiments of the disclosure, a piezoelectrically transduced bulk acoustic wave resonator can be designed to provide a temperature-stable frequency using nonlinear elasticity of semiconductor body.

In some embodiments of the disclosure, the resonator may be created from growing a piezoelectric transducer (e.g., Piezoelectric ScAlN-Metal stack) atop a substrate created from layers of single-crystal silicon and silicon dioxide. In this structure, the piezoelectric transducer serves for excitation of resonance mode in resonator.

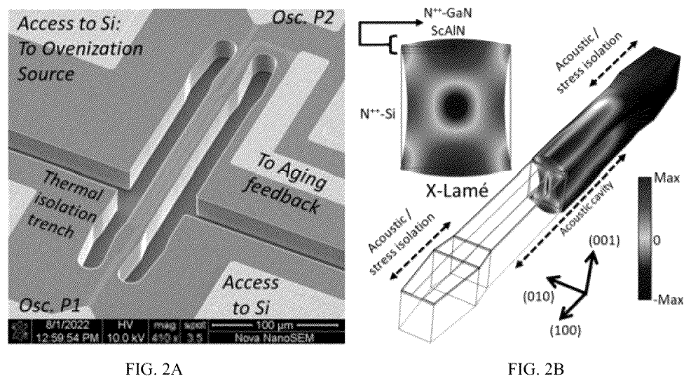

FIG. 2A shows an example resonator design, where resonator geometry is engineered to localize a bulk acoustic mode with high quality factor. In some embodiments, the resonator comprises two electrodes, deposited and patterned on piezoelectric layer. The electrodes serve as excitation and sensing port in a two-port architecture. FIG. 2B shows the simulated mode shape of the example resonator design when operating in cross-sectional Lamé mode.

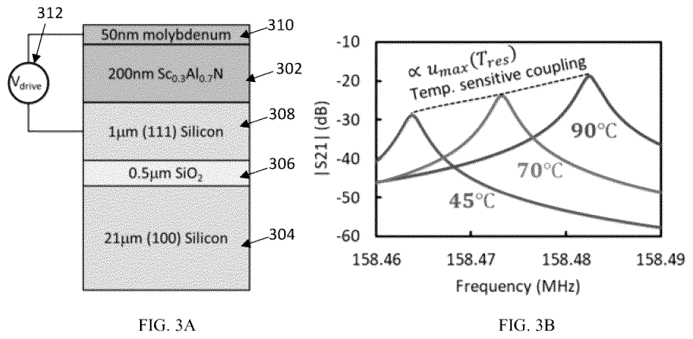

FIG. 3A shows a cross-sectional stack of an example resonator. The cross-sectional stack of the example resonator comprises a piezoelectric layer 302 deposited on the top of a substrate. In some embodiments, the piezoelectric layer 302 comprises Sc_{0.3}Al_{0.7}N. The substrate comprises a silicon layer 304, a silicon dioxide layer 306 deposited on the top of the silicon layer 304, and a silicon layer 308 deposited on the top of the silicon dioxide layer 306. The cross-sectional stack of the example resonator further comprises a metal layer 310 deposited on the piezoelectric layer 302. In some embodiments, the metal layer 310 may comprise molybdenum (MO), platinum (Pt), gold (Au), silver (Ag), copper (Cu), or aluminum (Al), etc.

FIG. 3B shows simulated transmission response of the example resonator at different temperatures. As shown in FIG. 3B, the resonator insertion-loss changes significantly with temperature variation, as a result of nonhomogeneous acoustic impedance across the resonator stack and corresponding variation in energy distribution across resonator at different temperatures.

In some embodiments, when the resonator is actuated with a voltage with a constant magnitude (e.g., in an oscillator with stable oscillation voltage), the temperature-dependence of insertion-loss translates to a temperature-dependent vibration amplitude (uₘₐₓ) that can be formulated as:

$${u}_{ma x} ( {T}_{res} ) = \frac{1}{2 π {f}_{res} ( {T}_{res} ) η} \cdot \frac{{V}_{drive}}{200 ( {10}^{\vert \frac{γ \cdot {T}_{0}}{{T}_{res} - {T}_{0}} \vert} - 1 )} \qquad ( 12 )$$

Here, Tᵣₑₛ is resonator temperature. fᵣₑₛ is resonance frequency. η is electromechanical transduction efficiency. V_{drive} is oscillator voltage (also referred to herein as oscillator drive voltage or drive voltage). γ and T₀ are constants defined by resonator cross-sectional profile (i.e., materials in resonator stack, their thickness and acoustic impedance). In some embodiments, the oscillator voltage 312 is the voltage difference between the metal layer 310 above the piezoelectric layer 302 and the Silicon layer 308 below the piezoelectric layer 302, as shown in FIG. 3A.

The temperature variation in uₘₐₓ result in additional terms in temperature-dependent resonator frequency, as a result of resonator elastic nonlinearity:

$${f}_{res} ( {T}_{res} ) ≅ {f}_{res} ( 0 ) [ 1 + {TCf}_{1} {T}_{res} + {TCf}_{2} {T}_{res}^{2} + {TCf}_{3} {T}_{res}^{3} + {TCf}_{4} {T}_{res}^{4} ] + {κ [ {u}_{ma x} ( 0 ) + \frac{{du}_{ma x}}{dT} {T}_{res} + \frac{{d}^{2} {u}_{ma x}}{{dT}^{2}} {T}_{res}^{2} ]}^{2} - {κ [ {u}_{ma x} ( 0 ) ]}^{2} \qquad ( 13 )$$

Here, TCfᵢ are temperature-coefficients of frequency of resonator when operating in linear regime (i.e., small V_{drive}). K is the amplitude-frequency coefficient defined by nonlinearities in clastic constants of resonator constituent materials.

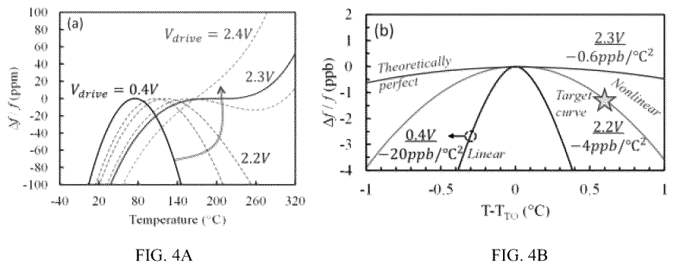

Incorporating Eq. (12) in Eq. (13), temperature characteristic can be tuned by changing oscillator drive voltage V_{drive} to compensate TCf₁ and TCf₂ of the resonator. FIGS. 4A and 4B show the simulated temperature characteristic of the example resonator with detailed designs in FIGS. 2A and 3A, for different V_{drive}. FIG. 4A shows the simulated temperature characteristic in a wide temperature range, and FIG. 4B shows that in a small temperature range around the turn-over point. As demonstrated in FIG. 4B, opting for 2.2V drive voltage (for the resonator with motional resistance of 1 kΩ) enables significant compensation of TCf₂ by four-times, from −20 ppb/° C.² in linear to −4 ppb/° C.² in clastic nonlinear regime. This approach enables the creation of oscillators and clocks with ultra-stable frequency independent from temperature.

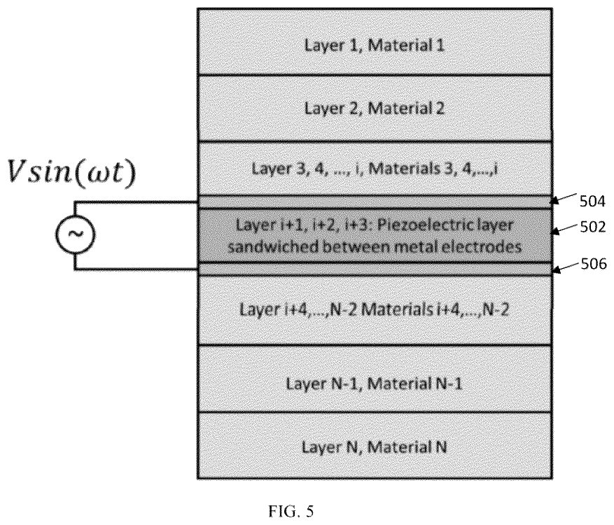

FIG. 5 shows a cross-sectional stack of another example piezoelectrically-actuated resonator. The example piezoelectrically-actuated resonator comprises stacking various layers of different materials, which includes in part one piezoelectric transducer. In some embodiments, the example piezoelectrically-actuated resonator comprises a piezoelectric layer 502, sandwiched between a metal electrode layer 504 and a metal electrode layer 506. The example piezoelectrically-actuated resonator further comprises a plurality of additional layers above the metal electrode layer 504 and below the metal electrode layer 506. Since the different temperature-sensitivity of acoustic properties for materials in stack result in a change in mechanical energy distribution at different temperatures, the temperature-dependent energy in piezoelectric layer can result in a temperature-dependent excitation force F when a constant voltage magnitude is applied across the resonator. Thus, the thickness of the various layers of different materials in the example piezoelectrically-actuated resonator may be designed to create the temperature-dependent excitation force (or temperature-dependent vibration amplitude) with desired functionality. The thickness (and/or the dimension) of the various layers of different materials may be determined based at least in part on multiphysics simulation to obtain the temperature-dependent excitation force (or temperature-dependent vibration amplitude) with desired functionality to compensate resonator frequency drift through nonlinearities. In some embodiments, the piezoelectric layer 502 may comprise scandium-aluminum-nitride (ScAlN). In some embodiments, the metal electrode layer 504 and the metal electrode layer 506 each may comprise molybdenum (MO), platinum (Pt), gold (Au), silver (Ag), copper (Cu), or aluminum (Al), etc. In some embodiments, each of the plurality of additional layers above the metal electrode layer 504 and below the metal electrode layer 506 may comprise silicon (Si), or Silicon Dioxide (SiO₂), etc.

In some other embodiments of the disclosure, a temperature-dependent voltage may be generated and applied to an electromechanical resonator to generate the temperature-dependent excitation force (or temperature-dependent vibration amplitude) with desired functionality to compensate resonator frequency drift through nonlinearities.

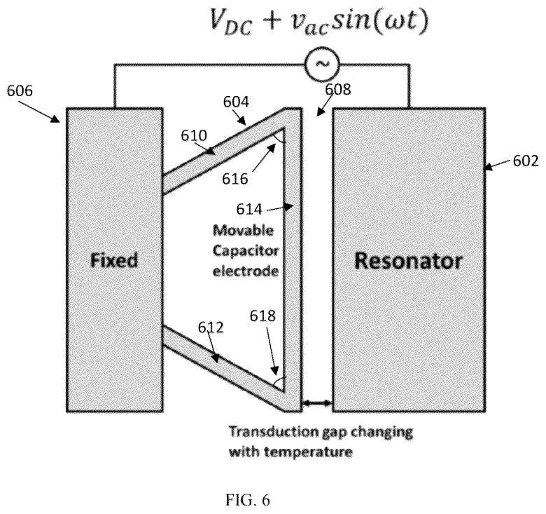

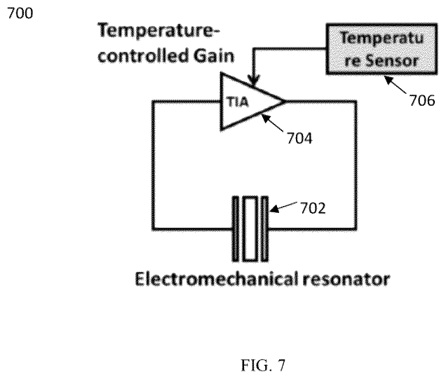

FIG. 6 shows an example capacitively-actuated resonator. The example capacitively-actuated resonator comprises a resonator 602, a movable capacitor electrode 604, and a fixed element 606. The movable capacitor electrode 604 comprises a first electrode 614 and two arms 610 and 612. In some embodiments, the first electrode 614 is substantially in parallel with the resonator 602. The two arms 610 and 612 each connects one end of the first electrode 614 to the fixed element 606. Each of the two arms and the first electrode 614 form an angle, i.e., angles 616 and 618. Due to thermal expansion, a width of a transduction gap 608 between the first electrode 614 and the resonator 602 (i.e., the distance between the first electrode 614 and the resonator 602) changes with temperature. The electrostatic excitation applied to the resonator varies with the change of the transduction gap. In some embodiments, the angles 616 and 618 and the dimensions of the first electrode 604 and the two arms 610 and 612 are designed so that the transduction gap is scaled by desired temperature-dependency that result in the temperature-dependent excitation force (or temperature-dependent vibration amplitude) with desired functionality to compensate resonator frequency drift through nonlinearities.

FIG. 7 shows an example embodiment of the disclosure based on controlling oscillator loop gain using local temperature sensing. In this embodiment, an example oscillator 700 comprises an example electromechanical resonator 702 coupled to an example transimpedance amplifier (TIA) 704 with temperature-controlled gain. In the oscillator 700, the temperature-controlled gain of the TIA 704 is designed so that the voltage across the electromechanical resonator 702 generates the temperature-dependent excitation force (or temperature-dependent vibration amplitude) with desired functionality to compensate resonator frequency drift through nonlinearities. In some embodiments, the oscillator 700 further comprises a temperature sensor that measures temperature and provides the corresponding values to the TIA 704.

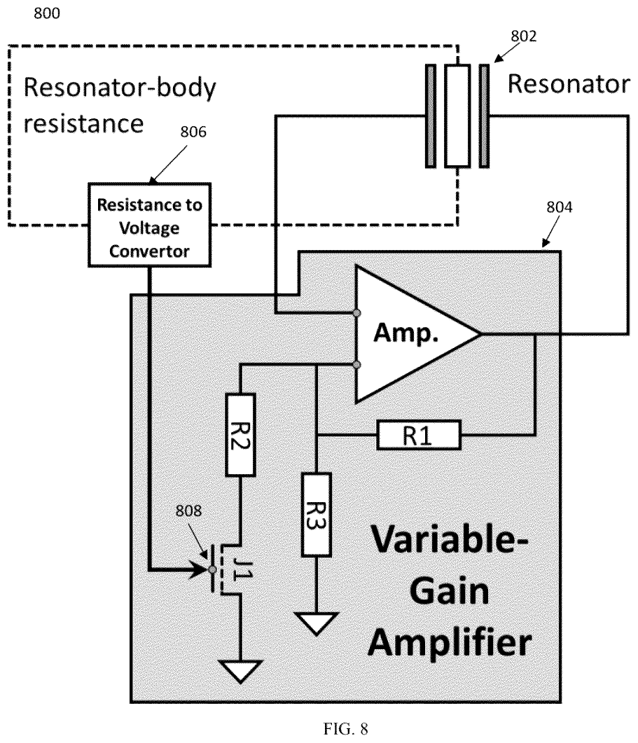

FIG. 8 shows another example embodiment of the disclosure based on controlling oscillator loop gain using local temperature sensing. In this embodiment, an example oscillator 800 comprises an example electromechanical resonator 802 coupled to an example transimpedance amplifier (TIA) 804 with temperature-controlled gain. In some embodiments, the oscillator 800 further comprises a resistance to voltage converter 806. The resistance to voltage converter 806 converts resistance of resonator body (i.e., silicon structural layer) of the electromechanical resonator 802 to voltage. The output of the resistance to voltage converter 806 is fed to a control gate of the TIA 804. The TIA 804 comprises a variable-gain circuit. The gain of the TIA is controlled by a voltage applied to the control gate of a transistor 808 disposed in the variable-gain circuit. In this embodiment, the variable-gain of the TIA 804 is controlled by the output of the resistance to voltage converter 806, which reflects the resonator temperature since the resistance of resonator body varies with temperature. The variable-gain of the TIA 804 can be designed so that the voltage across the electromechanical resonator 802 generates the temperature-dependent excitation force (or temperature-dependent vibration amplitude) with desired functionality to compensate resonator frequency drift through nonlinearities.

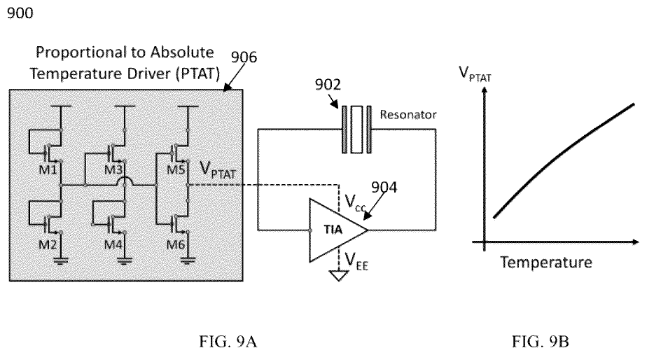

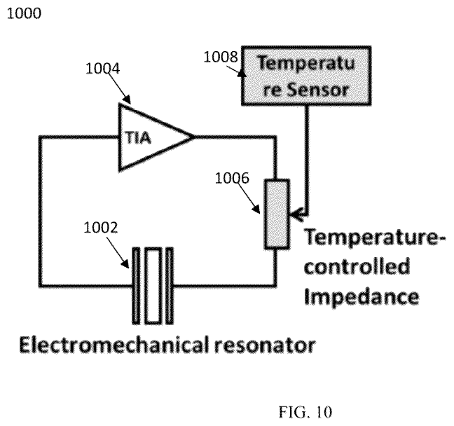

FIG. 9A shows another example embodiment of the disclosure based on controlling oscillator loop gain using local temperature sensing. In this embodiment, an example oscillator 900 comprises an example electromechanical resonator 902 coupled to an example transimpedance amplifier (TIA) 904 with temperature-controlled gain. In this embodiment, the TIA gain is controlled through changing its bias voltage V_{CC} using a proportional to absolute temperature circuit (PTAT) 906. In the PTAT circuit 906, the output voltage is an ascending function of temperature, as shown in FIG. 9B. The change in PTAT output voltage with temperature induces a change in TIA gain which corresponds to compensation of resonator frequency drift through nonlinearities.

FIG. 10 shows another example embodiment of the disclosure based on controlling oscillator loop gain using local temperature sensing. In this embodiment, an example oscillator 1000 comprises an example electromechanical resonator 1002 coupled to an example transimpedance amplifier (TIA) 1004 with a constant gain through a temperature-controlled impedance 1006. In this embodiment, impedance of the temperature-controlled impedance 1006 is controlled based on temperature to provide a temperature-dependent voltage across the electromechanical resonator 1002 to generate the temperature-dependent excitation force (or temperature-dependent vibration amplitude) with desired functionality to compensate resonator frequency drift through nonlinearities. In some embodiments, the oscillator 1000 further comprises a temperature sensor 1008.

### CONCLUSION

Various embodiments of the disclosure comprise novel methods and systems leveraging temperature-dependent nonlinearity in resonator operation to compensate frequency drift of a mechanical resonator due to temperature change. The methods and systems rely on generating force functions (and corresponding displacements) for the mechanical resonator with desirable magnitude and temperature-functionality to compensate resonator frequency drift through nonlinearities. The simulation results demonstrate the effectiveness of the methods. The disclosure also discusses various approaches for generating such force functions.

Many modifications and other embodiments of the disclosures set forth herein will come to mind to one skilled in the art to which these disclosures pertain having the benefit of the teachings presented in the foregoing description and the associated drawings. Therefore, it is to be understood that the disclosures are not to be limited to the specific embodiments disclosed and that modifications and other embodiments are intended to be included within the scope of the appended claims. Although specific terms are employed herein, they are used in a generic and descriptive sense only and not for purposes of limitation, unless described otherwise.

1. A method for compensating a frequency drift of a mechanical resonator due to temperature change comprising:
generating a drive voltage; and
applying the drive voltage to the mechanical resonator, wherein the drive voltage (1) excites elastic nonlinearity of the mechanical resonator, and (2) generates a temperature-dependent force or displacement enabling the mechanical resonator to compensate the frequency drift.

2. The method of claim 1, wherein the mechanical resonator is a piezoelectrically-actuated resonator, wherein the drive voltage has a constant magnitude.

3. The method of claim 2, wherein the piezoelectrically-actuated resonator comprises a piezoelectric layer, at least one metal layer, and a plurality of semiconductor layers, wherein a thickness of each of the piezoelectric layer and the plurality of semiconductor layers is designed so that the temperature-dependent force or displacement can be generated with the applied drive voltage.

4. The method of claim 1, wherein the drive voltage has a temperature-dependent magnitude.

5. The method of claim 4, wherein the mechanical resonator is a capacitively-actuated resonator, wherein a width of a transduction gap of the capacitively-actuated resonator varies with temperature, generating the drive voltage with the temperature-dependent magnitude.

6. The method of claim 4, wherein the drive voltage with the temperature-dependent magnitude is generated by a transimpedance amplifier with temperature-controlled gain.

7. The method of claim 6, wherein the transimpedance amplifier comprises a variable-gain circuit, wherein the temperature-controlled gain of the transimpedance amplifier is controlled by coupling a first voltage to an input port of the variable-gain circuit, wherein the first voltage is determined based at least in part on a temperature of the mechanical resonator.

8. The method of claim 7, wherein the first voltage is generated by a resistance to voltage converter based at least in part on the temperature of the mechanical resonator.

9. The method of claim 6, wherein the temperature-controlled gain of the transimpedance amplifier is controlled through changing a bias voltage of the transimpedance amplifier, wherein the bias voltage is generated by a proportional to absolute temperature circuit.

10. The method of claim 4, wherein the temperature-dependent drive voltage is generated by coupling the mechanical resonator to a transimpedance amplifier with a constant gain through a temperature-controlled impedance.

11. A system for compensating a frequency drift of a mechanical resonator due to temperature change comprising:
the mechanical resonator; and
a subsystem coupled to the mechanical resonator, wherein the subsystem generates and applies a drive voltage to the mechanical resonator, wherein the drive voltage (1) excites elastic nonlinearity of the mechanical resonator, and (2) generates a temperature-dependent force or displacement enabling the mechanical resonator to compensate the frequency drift.

12. The system of claim 11, wherein the mechanical resonator is a piezoelectrically-actuated resonator, wherein the drive voltage has a constant magnitude.

13. The system of claim 12, wherein the piezoelectrically-actuated resonator comprises a piezoelectric layer, at least one metal layer, and a plurality of semiconductor layers, wherein a thickness of each of the piezoelectric layer and the plurality of semiconductor layers is designed so that the temperature-dependent force or displacement can be generated with the applied drive voltage.

14. The system of claim 11, wherein the drive voltage has a temperature-dependent magnitude.

15. The system of claim 14, wherein the system is a capacitively-actuated resonator, wherein a width of a transduction gap of the capacitively-actuated resonator varies with temperature, generating the drive voltage with the temperature-dependent magnitude.

16. The system of claim 14, wherein the subsystem comprises a transimpedance amplifier with temperature-controlled gain, wherein the drive voltage with the temperature-dependent magnitude is generated by the transimpedance amplifier with temperature-controlled gain.

17. The system of claim 16, wherein the transimpedance amplifier comprises a variable-gain circuit, wherein the temperature-controlled gain of the transimpedance amplifier is controlled by coupling a first voltage to an input port of the variable-gain circuit, wherein the first voltage is determined based at least in part on a temperature of the mechanical resonator.

18. The system of claim 17, wherein the subsystem further comprises a resistance to voltage converter, wherein the first voltage is generated by the resistance to voltage converter based at least in part on the temperature of the mechanical resonator.

19. The system of claim 16, wherein the subsystem further comprises a proportional to absolute temperature circuit, wherein the temperature-controlled gain of the transimpedance amplifier is controlled through changing a bias voltage of the transimpedance amplifier, wherein the bias voltage is generated by the proportional to absolute temperature circuit.

20. The system of claim 14, wherein the subsystem further comprises a temperature-controlled impedance, wherein the temperature-dependent drive voltage is generated by coupling the mechanical resonator to a transimpedance amplifier with a constant gain through the temperature-controlled impedance.
